(19) United States
(12) Patent Application Publication
(10) Pub. No.: US 2017/0064825 A1
(43) Pub. Date: Mar. 2, 2017

(54) PRINTED WIRING BOARD AND METHOD FOR MANUFACTURING PRINTED WIRING BOARD

(71) Applicant: IBIDEN CO., LTD., Ogaki (JP)

(72) Inventors: Teruyuki ISHIHARA, Ogaki (JP); Haiying MEI, Ogaki (JP); Hiroyuki BAN, Ogaki (JP)

(73) Assignee: IBIDEN CO., LTD., Ogaki (JP)

(21) Appl. No.: 15/252,264

(22) Filed: Aug. 31, 2016

(30) Foreign Application Priority Data
Aug. 31, 2015 (JP) 2015-170312

(51) Int. Cl. H05K 1/11; H05K 1/03; H05K 1/18; H05K 1/02; H05K 3/40; H05K 3/46

(52) U.S. Cl. CPC H05K 1/113; H05K 3/4038; H05K 3/4647; H05K 1/183; H05K 1/0298; H05K 1/0373; H05K 2203/1189; H05K 2201/068

(57) ABSTRACT

A printed wiring board includes a first circuit substrate having first and second surfaces, and a second circuit substrate having third and fourth surfaces such that the first substrate is laminated on the third surface and that the first and third surfaces are opposing each other. The second substrate includes a conductor layer, a first insulating layer including reinforcing material and formed on the conductor layer, and mounting via conductors formed in the first insulating layer and connected to the conductor layer such that the second substrate has a mounting area on the third surface and that the mounting via conductors have via bottoms forming pads positioned to mount an electronic component in the mounting area, and the first substrate includes an insulating layer which does not contain reinforcing material and has an opening through the insulating layer and exposing the via bottoms forming the pads in the mounting area.

### CROSS-REFERENCE TO RELATED APPLICATIONS

The present application is based upon and claims the benefit of priority to Japanese Patent Application No. 2015-170312, filed Aug. 31, 2015, the entire contents of which are incorporated herein by reference.

### BACKGROUND OF THE INVENTION

### Field of the Invention

The present invention relates to a printed wiring board and a method for manufacturing the printed wiring board, the printed wiring board including a second circuit substrate and a first circuit substrate, the second circuit substrate having a mounting area, and the first circuit substrate having an opening for exposing the mounting area.

### Description of Background Art

Japanese Patent Laid-Open Publication No. 2015-060912 describes a package substrate for mounting a semiconductor element, the package substrate including a multilayer base substrate and a cavity substrate, the base substrate having a mounting area for mounting an electronic component, and the cavity substrate having a cavity for exposing the mounting area. The entire contents of this publication are incorporated herein by reference.

### SUMMARY OF THE INVENTION

According to one aspect of the present invention, a printed wiring board includes a first circuit substrate having a first surface and a second surface on the opposite side with respect to the first surface, and a second circuit substrate having a third surface and a fourth surface on the opposite side with respect to the third surface such that the first circuit substrate is laminated on the third surface and that the first surface and the third surface are opposing each other. The second circuit substrate includes a first conductor layer, a first resin insulating layer including a reinforcing material and formed on the first conductor layer, and mounting via conductors formed in the first resin insulating layer and connected to the first conductor layer such that the second circuit substrate has a mounting area on the third surface and that the mounting via conductors have via bottoms forming pads and positioned to mount an electronic component in the mounting area, respectively, and the first circuit substrate includes an insulating layer which does not contain a reinforcing material and has an opening portion formed through the insulating layer and exposing the via bottoms forming the pads formed in the mounting area.

According to another one aspect of the present invention, a method for manufacturing a printed wiring board includes forming, on a support plate, an insulating layer of a first circuit substrate, forming a frame-shaped groove for an opening portion of the first circuit substrate in the insulating layer such that the frame-shaped groove reaches the support plate, forming a release layer on a surface of the insulating layer such that the release layer extends to cover the frame-shaped groove, forming, on the surface of the insulating layer, a first resin insulating layer of a second circuit substrate such that the first resin insulating layer covers the release layer formed on the insulating layer of the first circuit substrate, removing the support plate from the insulating layer of a first circuit substrate such that the support plate is separated from a structure including the insulating layer of the first circuit substrate and the first resin insulating layer of the second circuit substrate, removing a portion of the insulating layer surrounded by the frame-shaped groove from the structure including the insulating layer of the first circuit substrate and the first resin insulating layer of the second circuit substrate such that the opening portion is formed in the insulating layer of the first circuit substrate, and removing the release layer from the structure including the insulating layer of the first circuit substrate and the first resin insulating layer of the second circuit substrate such that a mounting area for mounting an electronic component on the second circuit substrate is formed by exposing in the opening portion of the insulating layer. The insulating layer of the first circuit substrate does not contain a reinforcing material, and the first resin insulating layer of the second circuit substrate includes a reinforcing material.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a printed wiring board according to a first embodiment of the present invention;

FIG. 1B is a plan view illustrating a first circuit substrate and a mounting area that is exposed from an opening of the first circuit substrate;

FIG. 2A is a cross-sectional view of a semiconductor device according to the first embodiment;

FIG. 2B is a cross-sectional view of an application example of the semiconductor device;

FIG. 3A-3E are manufacturing process diagrams of the printed wiring board of the first embodiment;

FIG. 4A-4C are manufacturing process diagrams of the printed wiring board of the first embodiment;

FIG. 5A and 5B are manufacturing process diagrams of the printed wiring board of the first embodiment;

FIG. 6A-6C are manufacturing process diagrams of the printed wiring board of the first embodiment;

FIG. 7A-7D are manufacturing process diagrams of the printed wiring board of the first embodiment;

FIG. 8A-8B are a cross-sectional view and a plan view of a printed wiring board according to a modified embodiment of the first embodiment of the present invention;

FIG. 9 is a cross-sectional view of a printed wiring board according to a second embodiment of the present invention;

FIG. 10A-10C are manufacturing process diagrams of the printed wiring board of the second embodiment; and

FIG. 11A-11C are manufacturing process diagrams of the printed wiring board of the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

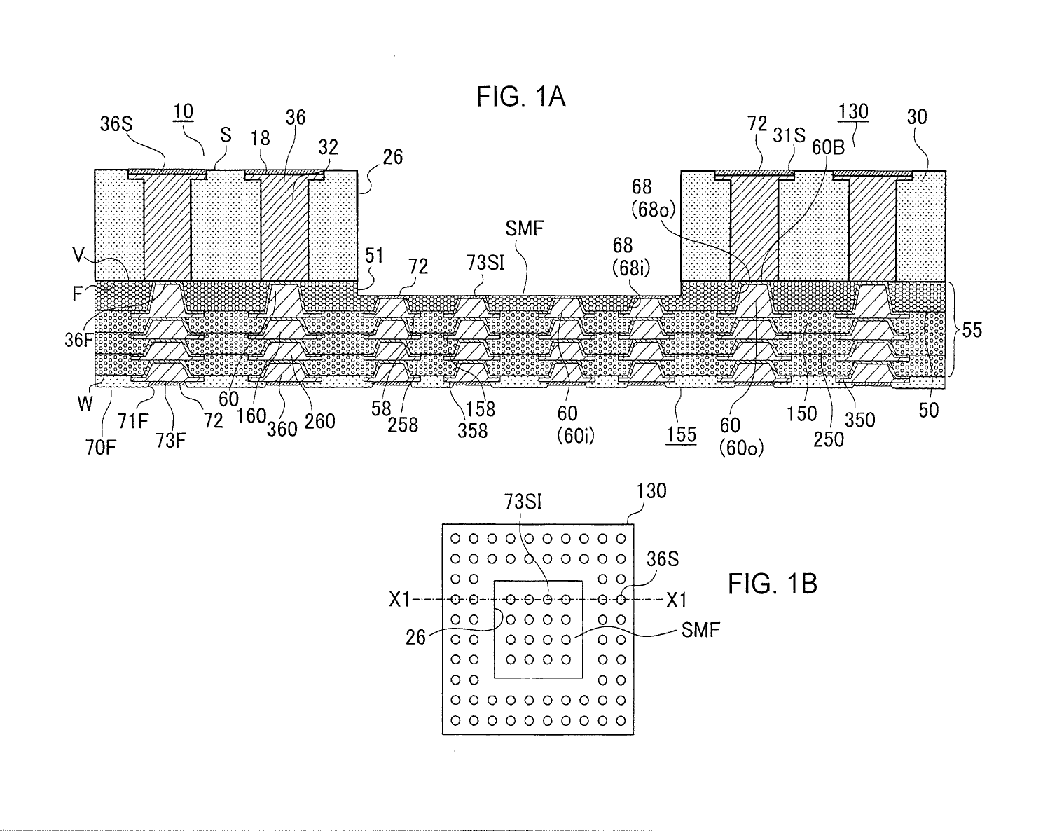

FIG. 1A illustrates a printed wiring board 10 of a first embodiment. The printed wiring board 10 of the first embodiment includes a first circuit substrate 130 that has a first surface (F) and a second surface (S) that is on an opposite side of the first surface (F), and a second circuit substrate 155 that has a third surface (V) and a fourth surface (W) that is on an opposite side of the third surface (V).

The second circuit substrate 155 illustrated in FIG. 1A is formed by a build-up layer 55 that includes conductor layers (58, 158, 258, 358) and a first resin insulating layer 50, a second resin insulating layer 150, a third resin insulating layer 250 and a fourth resin insulating layer 350 that are alternately laminated. The second circuit substrate 155 is laminated on the first surface (F) of the first circuit substrate 130. The third surface (V) of the second circuit substrate 155 and the first surface (F) of the first circuit substrate 130 are in contact with each other. The first resin insulating layer 50 that forms the build-up layer 55 of the second circuit substrate 155 is formed from a reinforcing material, a resin such as epoxy, and an inorganic filler (inorganic particles) such as silica or alumina. For example, the first resin insulating layer 50 is formed from a prepreg that includes a core material by impregnating a glass cloth with an epoxy-based resin and an inorganic filler. Examples of the reinforcing material include a glass fiber, a glass cloth and an aramid fiber. The second resin insulating layer 150, the third resin insulating layer 250 and the fourth resin insulating layer 350 that form the build-up layer 55 of the second circuit substrate 155 are formed from a resin and an inorganic filler, and do not contain a reinforcing material. Via conductors (60, 160, 260, 360) that respectively penetrate the resin insulating layers (50, 150, 250, 350) are respectively formed on the resin insulating layers. The via conductors (60, 160, 260, 360) are each formed in a tapered shape that is gradually reduced in diameter from the fourth surface (W) side toward the third surface (V) side. Conductor layers that are adjacent to each other are connected by the via conductors (60, 160, 260, 360).

The second circuit substrate 155 has a mounting area (SMF) illustrated in FIG. 1B at a substantially central portion of the third surface (V). An X1-X1 cross section in FIG. 1B corresponds to FIG. 1A. The mounting area (SMF) is exposed by an opening 26 of the first circuit substrate. A recess 51 that forms a bottom part of the opening 26 is formed in the first resin insulating layer 50. An electronic component such as an IC chip is mounted on the mounting area (SMF).

The first circuit substrate 130 illustrated in FIG. 1A is formed by an insulating layer 30, through-hole conductors 36, and first terminals (36F) and second terminals (36S) of the through-hole conductors 36, the insulating layer 30 being formed from a mold resin that contains an inorganic filler but does not contain a reinforcing material, and the through-hole conductors 36 being formed from conductor posts 32. The insulating layer 30 has the first surface (F) and the second surface (S) that is on the opposite side of the first surface (F). The first terminals (36F) are formed on the first surface (F), and the second terminals (36S) are formed on the second surface (S). The first circuit substrate 130 further has the opening 26 for exposing the mounting area (SMF) of the second circuit substrate 155.

As illustrated in FIG. 1A, the first resin insulating layer 50 is formed on the first surface (F) of the first circuit substrate 130 and on the first terminals (36F). Openings 68 (68i, 68o) for via conductors 60 (60i, 60o) that penetrate the first resin insulating layer 50 are formed in the first resin insulating layer 50. The conductor layer 58 in the second circuit substrate 155 is formed on the first resin insulating layer 50. The via conductors 60 are formed in the openings 68 for the via conductors 60. The via conductors 60 include connection via conductors (60o) that connect the conductor layer (first conductor layer in the second circuit substrate) 58 and the first terminals (36F), and mounting via conductors (first via conductors) (60i) for mounting an electronic component. It is preferable that the connection via conductors (60o) be directly connected to the first terminals (36F) of the through-hole conductors 36 in the first circuit substrate 130.

The mounting via conductors (60i) are formed in the mounting area (SMF). The mounting via conductors (60i) are formed in the openings (68i) for the via conductors of the first resin insulating layer 50. Bottoms (C4 pads) (73SI) of the mounting via conductors (60i) are exposed by the openings (68i). Further, the C4 pads (73SI) are exposed by the opening 26 of the first circuit substrate 130. The bottoms (C4 pads) (73SI) of the mounting via conductors (60i) are exposed by the opening 26 and the openings (68i). The connection via conductors (60o) are formed in the openings (68o) of the first resin insulating layer 50. Bottoms (60B) of the connection via conductors (60o) are directly connected to the first terminals (36F) of the through-hole conductors 36.

The printed wiring board 10 can have a solder resist layer (70F) of the build-up layer 55 on the outermost fourth resin insulating layer 350 and the outermost conductor layer 358 of the second circuit substrate 155. Openings (71F) that expose the conductor layer (uppermost conductor layer) 358 are formed in the solder resist layer (70F) of the build-up layer 55. Portions of the conductor layer 358 that are exposed by the openings (71F) function as pads (73F) that connect to a motherboard. A protective film 72 can be formed on each of the pads (73F). The protective film 72 is a film for preventing oxidation of the pads (73F). The protective films 72 are each formed, for example, by a Ni/Au, Ni/Pd/Au, Pd/Au or OSP (Organic Solderability Preservative) film.

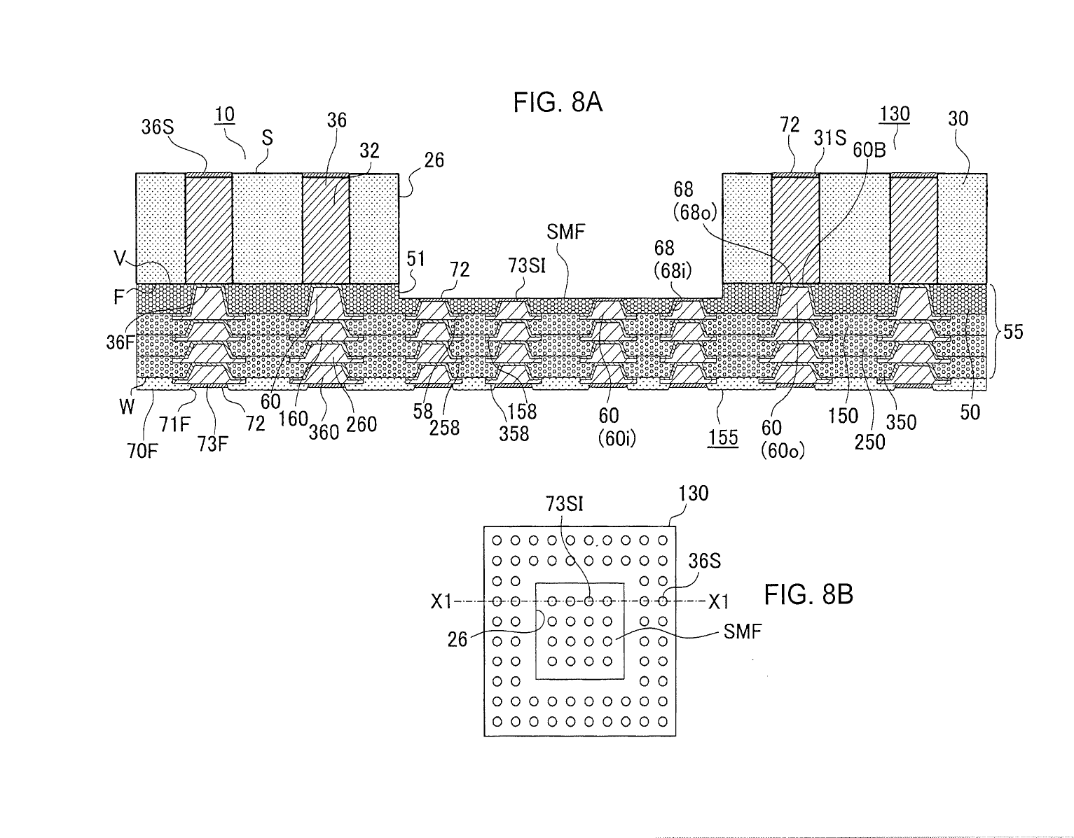

The through-hole conductors 36 of the first circuit substrate 130 are each formed from an embedded wiring 18 that is formed on the second surface (S) side, and a column-shaped conductor post 32. However, as illustrated in FIG. 8A-8B, it is also possible that the embedded wiring 18 on the second surface (S) side is not provided. That is, it is possible that the embedded wiring 18 on the second surface (S) side is provided or not provided. The first terminals (36F) of the through-hole conductors 36 are respectively formed by first surface (F) side end portions of the conductor posts 32. The first terminals (36F) are formed on substantially the same plane as the first surface (F) of the first circuit substrate 130. The second terminals (36S) of the through-hole conductors 36 on the second surface (S) side are formed by exposed surfaces of the embedded wirings 18 on the second surface (S) side. The second terminals (36S) are recessed from the second surface (S) of the first circuit substrate 130. The first circuit substrate 130 has openings (31S) that respectively expose the second terminals (36S) that are recessed from the second surface (S). A protective film 72 can be formed on each of the second terminals (36S) and on each of the C4 pads (73SI).

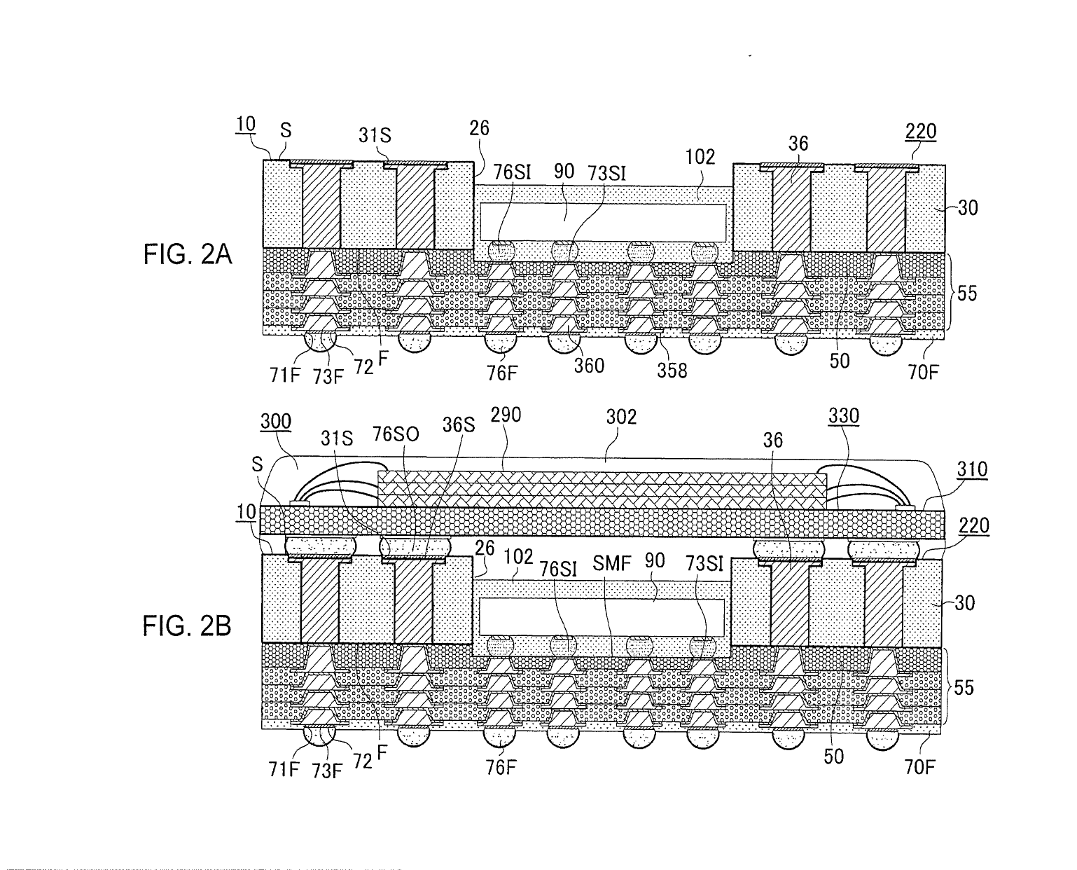

FIG. 2A illustrates a first application example (semiconductor device) 220 of the printed wiring board 10 of the present embodiment. The first application example 220 is a package substrate (first package substrate).

In the semiconductor device 220, an electronic component 90 such as an IC chip is accommodated in the opening 26 of the first circuit substrate 130. The IC chip 90 is mounted by solder bumps (76SI) on the C4 pads (73SI) that are exposed from the opening 26. A filling resin 102 that seals the IC chip is filled in the opening 26.

FIG. 2B illustrates a second application example (POP module) 300 of the printed wiring board 10 of the present embodiment. In the second application example, a second package substrate 330 is mounted on the semiconductor device 220 via connecting bodies (76SO). The second package substrate 330 includes an upper substrate 310 and an electronic component 290 such as a memory that is mounted on the upper substrate 310. The connecting bodies (76SO) are respectively formed on the second terminals (36S) that are respectively exposed by the upper side openings (31S). In FIG. 2B, the connecting bodies (76SO) are solder bumps (76SO). Examples of the connecting bodies other than solder bumps are conductor posts (not illustrated in the drawings) such as plating posts or pins. The plating posts or pins each have a shape of a circular cylinder. A right circular cylinder is preferred. A mold resin 302 that seals the electronic component 290 is formed on the upper substrate 310.

The printed wiring board 10 may have solder bumps (76F), which are for connecting to a motherboard, on the pads (73F) that are exposed from the openings (71F) of the solder resist layer (70F) on the build-up layer 55.

The filling resin 102 that seals the IC chip 90, and the insulating layer 30 that forms the first circuit substrate 130, are each formed from a mold resin that contains an inorganic filler but does not contain a reinforcing material. An example of the mold resin is a resin that primarily contains an epoxy-based resin or a BT (bismaleimide triazine) resin. Examples of the inorganic filler include particles formed from at least one selected from a group of an aluminum compound, a calcium compound, a potassium compound, a magnesium compound and a silicon compound. The examples of the inorganic filler further include silica, alumina, dolomite, and the like. In the first embodiment, it is preferable that the filling resin 102 and the insulating layer 30 have the same component composition. At least, it is desirable that a difference between a coefficient of thermal expansion of the insulating layer 30 and a coefficient of thermal expansion of the filling resin 102 be less than 10 ppm/° C. Further, it is preferable that a difference between a content rate of the inorganic filler contained in the insulating layer 30 and a content rate of the inorganic filler contained in the filling resin 102 be less than 10% by weight. The filling resin 102 and the insulating layer 30 are formed of a material (component composition) different from that of the first resin insulating layer 50. The filling resin 102 and the insulating layer 30 contain 70-85% by weight of the inorganic filler and have a coefficient of thermal expansion (CTE) of about 10 ppm/° C. The first resin insulating layer 50 contains 30-45% by weight of the, inorganic filler, and has a coefficient of thermal expansion (CTE) of about 39 ppm/° C. It is preferable that the difference in coefficient of thermal expansion between the insulating layer 30 and the filling resin 102 be less than the difference in coefficient of thermal expansion between the insulating layer 30 and the first resin insulating layer 50.

It is desirable that the content (percent by weight) of the inorganic filler contained in the filling resin 102 and the insulating layer 30 be 1.5 or more times the content (percent by weight) of the inorganic filler contained in the first resin insulating layer 50, and the coefficient of thermal expansion of the filling resin 102 and the insulating layer 30 be half or less than half the coefficient of thermal expansion of the first resin insulating layer 50. By allowing the filling resin 102 and the insulating layer 30 to have the same component composition, a crack is less likely to occur in the first resin insulating layer 50.

Since the printed wiring board 10 of the first embodiment uses the highly rigid insulating layer 30, warpage of the printed wiring board 10 can be reduced. In the printed wiring board 10 of the first embodiment, the first resin insulating layer 50 that is adjacent to the highly rigid insulating layer 30 contains a reinforcing material and has a high rigidity, and thus, a crack is unlikely to occur. Further, the second resin insulating layer 150, the third resin insulating layer 250 and the fourth resin insulating layer 350, which are distant from the insulating layer 30, do not contain a reinforcing material, and thus, an overall thickness can be reduced.

In the printed wiring board 10 of first embodiment, the pads (73SI) for mounting the electronic component 90 are the bottoms of the mounting via conductors (60i). The pads (73SI) do not have lands for mounting the electronic component. As a result, a size of each of the pads (73SI) for mounting the electronic component can be reduced. Therefore, a pitch of the pads (73SI) is narrowed, and a size of the printed wiring board 10 is reduced. Warpage of the printed wiring board 10 is reduced. Connection reliability between the printed wiring board 10 and the electronic component is improved. The printed wiring board 10 that allows an electronic component to be easily mounted can be provided.

### Method for Manufacturing Printed Wiring Board of First Embodiment

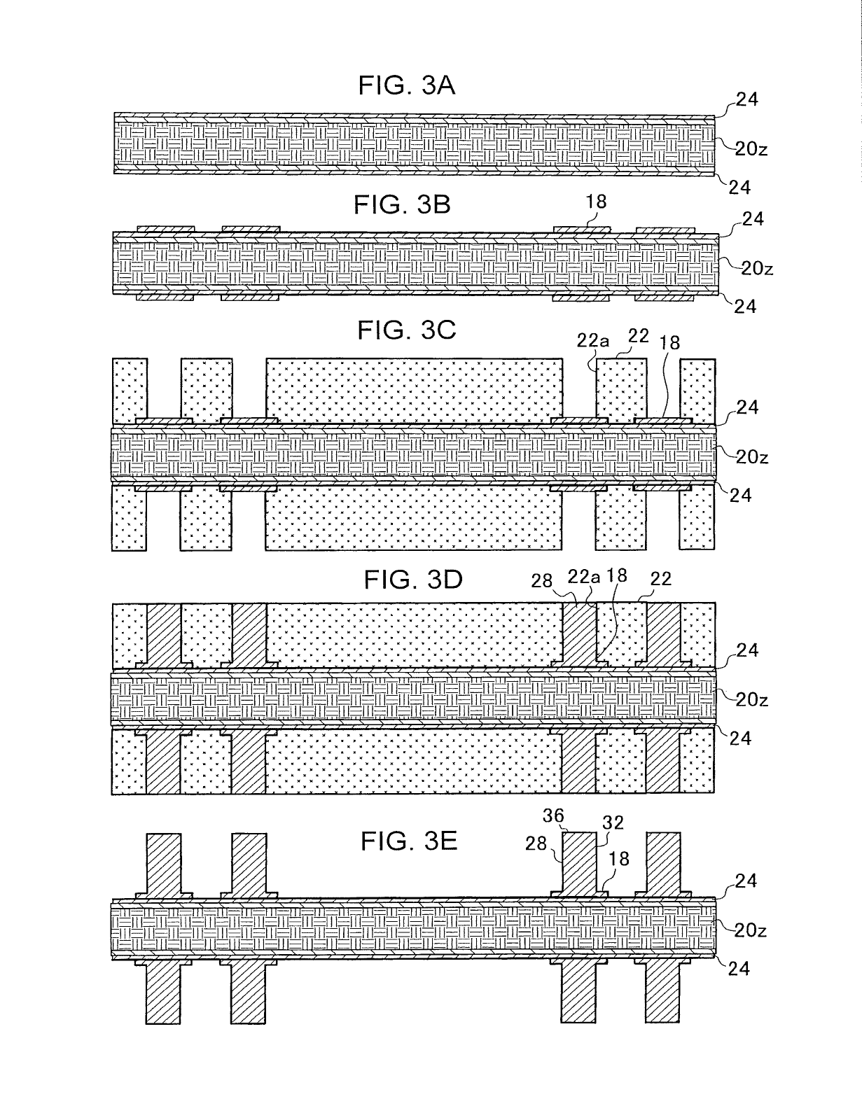

A method for manufacturing the printed wiring board 10 of the first embodiment is illustrated in FIG. 3A-7D.

A support plate (20z) and a metal foil 24 are prepared (FIG. 3A). In FIG. 3A, the metal foil 24 is laminated on the support plate (20z). Examples of the support plate (20z) include a metal plate and a double-sided copper-clad laminated plate. Examples of the metal foil 24 include a copper foil and a nickel foil. The embedded wirings 18 are formed on the metal foil 24 by electrolytic copper plating (FIG. 3B). A plating resist 22 having openings (22a) for forming conductor posts are formed (FIG. 3C). An electrolytic plating film 28 is formed in each of the openings (22a) of the plating resist 22 (FIG. 3D). The plating resist 22 is removed. The conductor posts 32 are respectively formed from the electrolytic plating films 28, and the through-hole conductors 36 that each include an embedded wiring 18 and a conductor post 32 are completed (FIG. 3E). The conductor posts 32 are respectively formed from the electrolytic plating films 28 only. However, it is possible that the embedded wirings 18 are not formed. In this case, the conductor posts 32 may be directly formed on the metal foil 24.

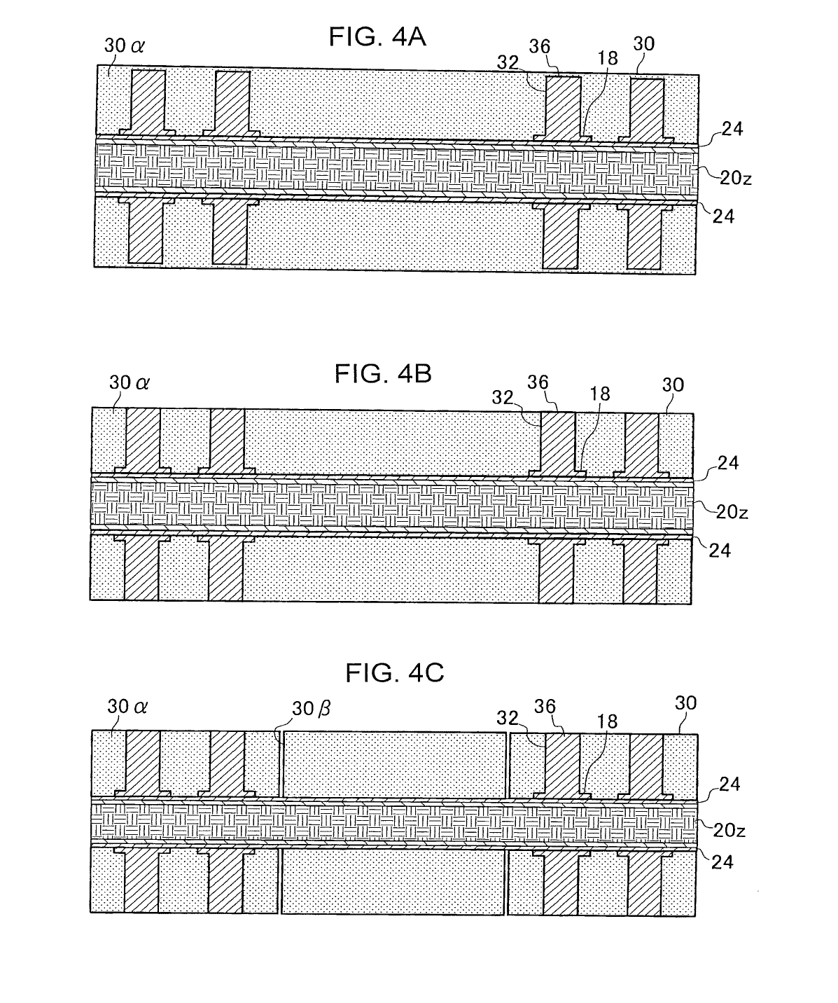

The insulating layer 30 is formed on the conductor posts 32 and on the metal foil 24 from a mold resin, and a first intermediate (30α) is completed, which includes the metal foil 24, the insulating layer 30 and the conductor posts 32 (FIG. 4A). Content of an inorganic filler of the insulating layer 30 is 70-85% by weight. A surface of the insulating layer 30 and the conductor posts 32 are polished and flattened (FIG. 4B).

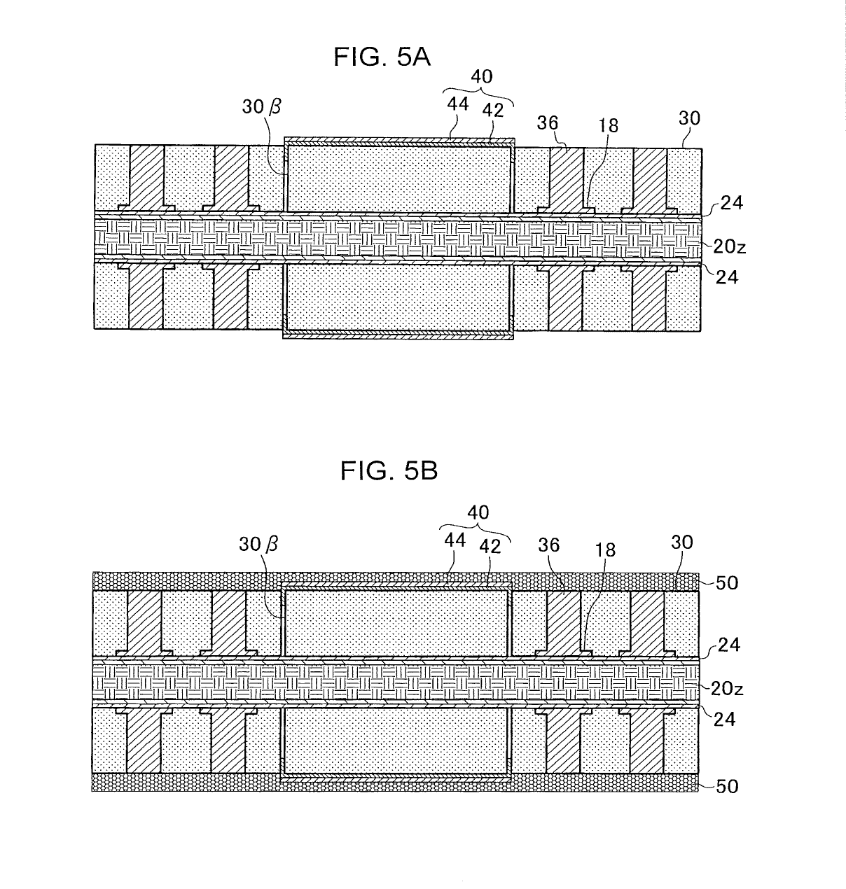

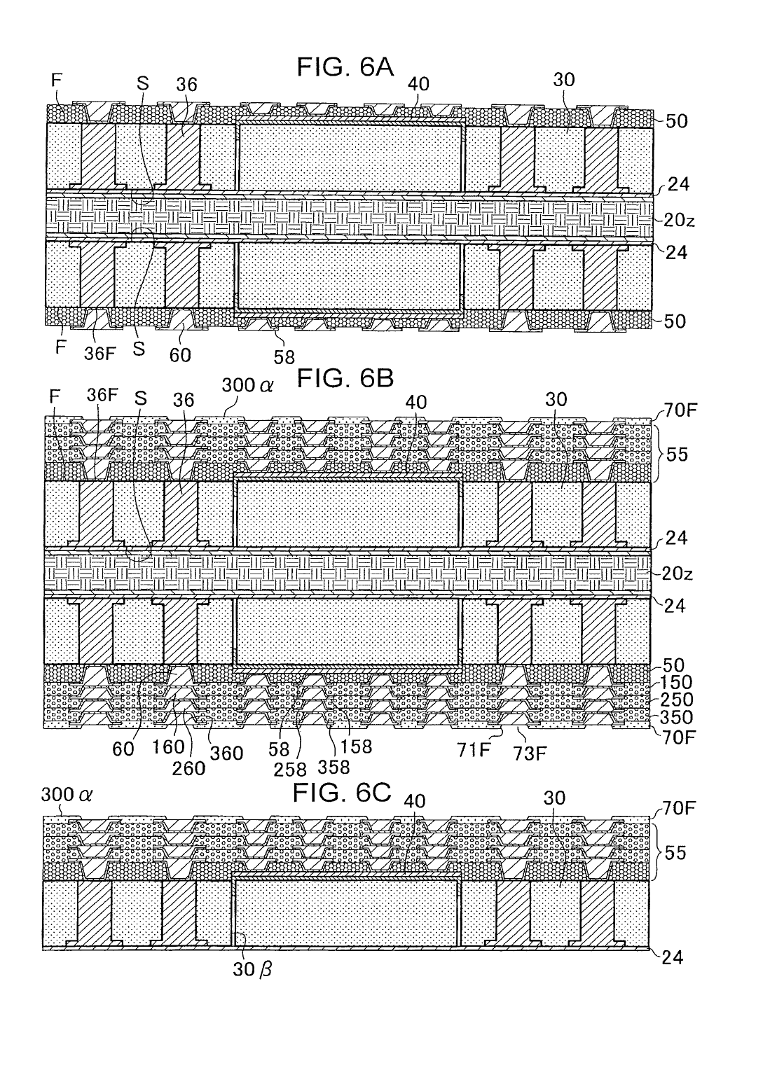

A frame-shaped groove (30β), which reaches the metal foil 24 of the support plate (20z) and is for forming an opening for accommodating an electronic component, is formed in a central portion of the insulating layer 30 using laser (FIG. 4C). In this case, through-hole conductors 36 may also be formed in a portion surrounded by the frame-shaped groove (30β). This allows localized stress concentration and warpage due to uneven distribution of conductors to be suppressed. Further, it allows the portion surrounded by the frame-shaped groove (30β) to be easily peeled off. A release layer 40 is provided so as to cover the frame-shaped groove (30β). The release layer 40 is formed by laminating a copper foil 44 on a release film 42 (FIG. 5A). A film for a resin insulating layer is laminated on the insulating layer 30 and on the release layer 40 and is cured, and the first resin insulating layer 50 is formed (FIG. 5B). The via conductors 60 that penetrate the first resin insulating layer 50 are formed, and the conductor layer 58 is formed on the first resin insulating layer 50. The via conductors 60 are respectively directly connected to the first terminals (36F) of the through-hole conductors 36 (FIG. 6A).

The second resin insulating layer 150 is formed on the first resin insulating layer 50 and the conductor layer 58. The via conductors 160, which penetrate the second resin insulating layer 150, and the conductor layer 158 are formed. The third resin insulating layer 250 is formed on the second resin insulating layer 150 and the conductor layer 158, and the via conductors 260, which penetrated the third resin insulating layer 250, and the conductor layer 258 are formed. The fourth resin insulating layer 350 is formed on the third resin insulating layer 250 and the conductor layer 258, and the via conductors 360, which penetrate the fourth resin insulating layer 350, and the conductor layer 358 are formed. As a result, the build-up layer 55 is completed, which includes the first resin insulating layer 50, the second resin insulating layer 150, the third resin insulating layer 250, the fourth resin insulating layer 350, the via conductors (60, 160, 260, 360), and the conductor layers (58, 158, 258, 358). The solder resist layer (70F) is formed on the build-up layer 55. The openings (71F) that respectively expose the pads (73F) are formed in the solder resist layer (70F) using laser. As a result, a second intermediate (300α) is formed (FIG. 6B).

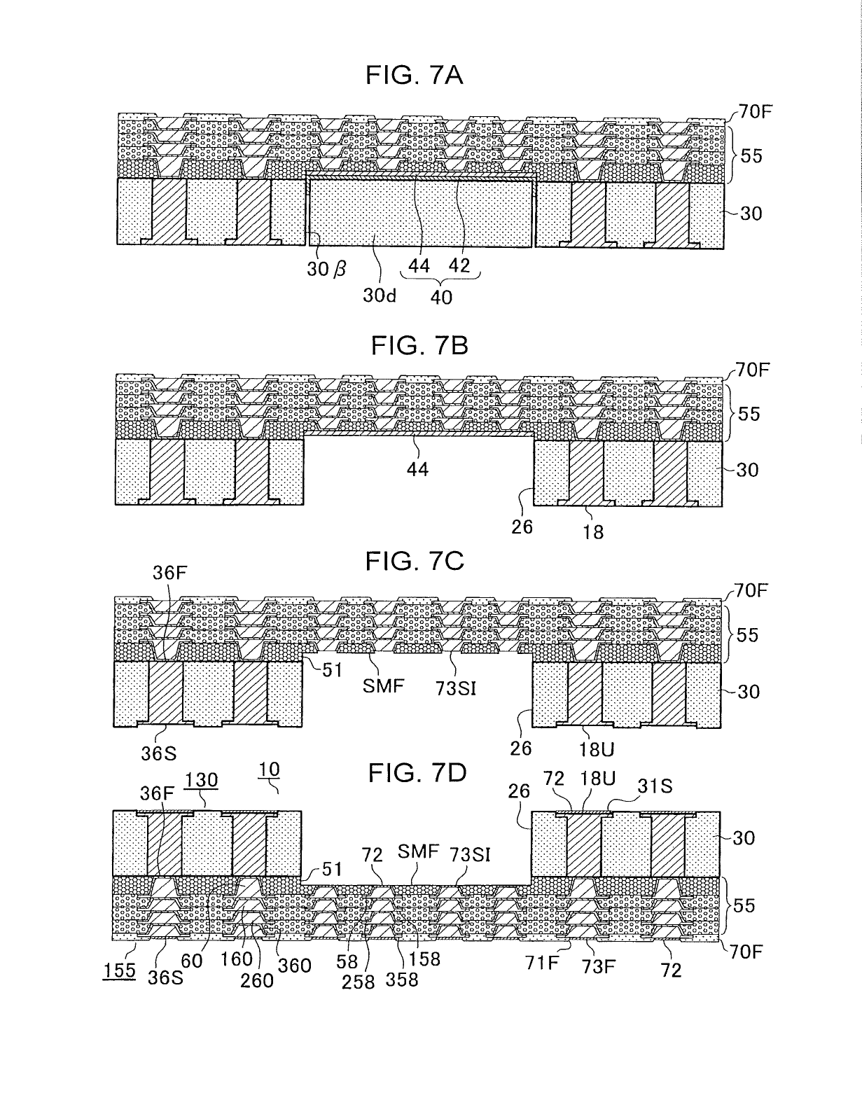

The second intermediate (300α) is separated from the support plate (20z) (FIG. 6C). By removing the metal foil 24 by etching, the frame-shaped groove (30β) is exposed (FIG. 7A). By peeling off a portion (30d) surrounded by the frame-shaped groove (30β) in the insulating layer 30 together with the release film 42 of the release layer 40, the opening 26 is formed (FIG. 7B). By etching, the copper foil 44 is removed, and upper surfaces (18U) of the embedded wirings 18 are recessed from the second surface (S) of the insulating layer 30. By the removal of the copper foil 44, the recess 51 of the first resin insulating layer 50 is exposed as the mounting area (SMF) in the opening 26 (FIG. 7C). Then, by Ni plating and Au plating, the protective films 72 are respectively formed on the upper surfaces (18U) of the embedded wirings 18, on the pads (73F), and on the C4 pads (73SI). The printed wiring board 10 having the first circuit substrate 130 and the second circuit substrate 155 is completed (FIG. 7D).

The IC chip 90 is mounted on the printed wiring board 10 via the solder bumps (76SI) on the C4 pads (73SI), and the IC chip 90 is sealed by the filling resin (mold resin) 102. However, it is also possible that the solder bumps (76SI) are not formed on the C4 pads (73SI) but on pads on the IC chip side. The first package substrate (semiconductor device) 220 is completed (FIG. 2A). The IC chip 90 is accommodated in the opening 26. The IC chip 90 does not extend to the outside of the opening 26. The second package substrate 330 is mounted on the first package substrate 220 via the solder bumps (76SO) (FIG. 2B). The POP substrate (application example) 300 is completed.

### Second Embodiment

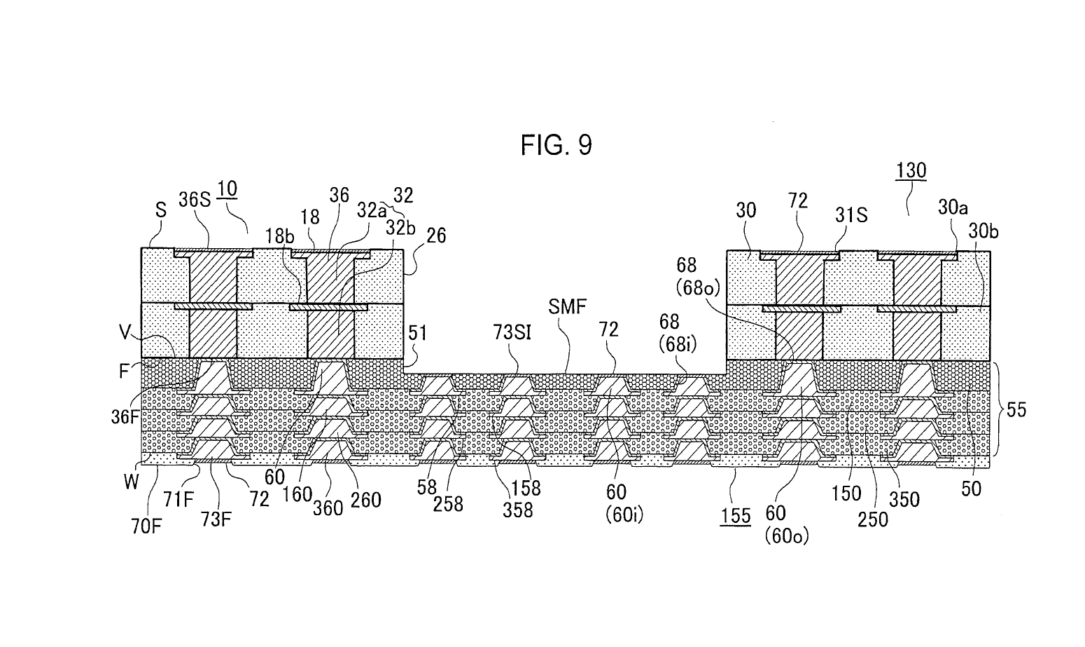

FIG. 9 illustrates a cross section of a printed wiring board 10 of a second embodiment.

Conductor posts 32 of an insulating layer 30 of the printed wiring board 10 of the second embodiment are each formed to have a two-stage structure that includes a first conductor post part (32a) and a second conductor post part (32b). An embedded wiring (18b) is interposed between the first conductor post part (32a) and the second conductor post part (32b). The insulating layer 30 is formed to have a two-layer structure that includes a first insulating layer (30a) and a second insulating layer (30b). The first conductor post part (32a) is embedded in the first insulating layer (30a). The second conductor post part (32b) is embedded in the second insulating layer (30b).

### Method for Manufacturing Printed Wiring Board of Second Embodiment

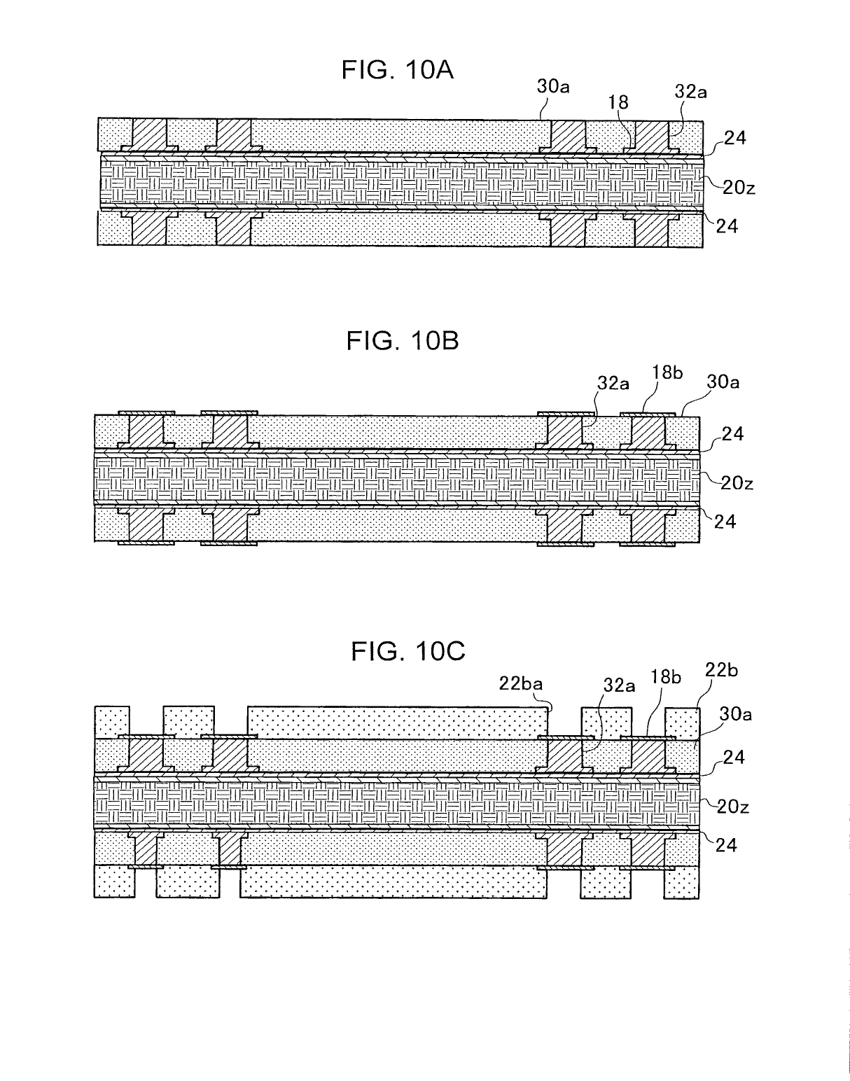

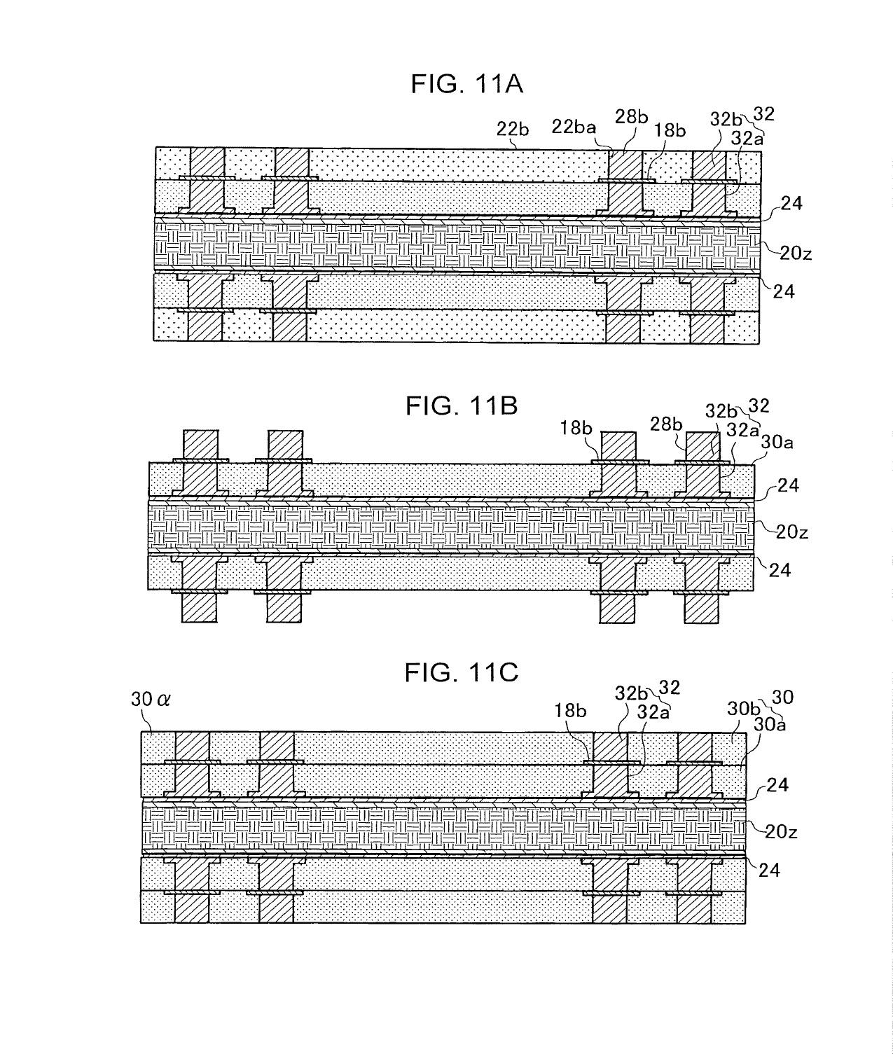

A method for manufacturing the printed wiring board 10 of the second embodiment is illustrated in FIG. 10A-11C.

Similar to the above-described first embodiment, the embedded wirings 18, the first conductor post parts (32a) and the first insulating layer (30a) are formed on the metal foil 24 of the support plate (20z) (FIG. 10A). The first insulating layer (30a) is formed from a mold resin. Here, a thickness of the first insulating layer (30a) is half that of the insulating layer 30 of the first embodiment. Therefore, a height of the first conductor post parts (32a) that are formed by electrolytic plating is half that of the conductor posts 32 of the first embodiment, and the first conductor post parts (32a) can be formed in a short time.

The embedded wirings (18b) are respectively formed on the first conductor post parts (32a) (FIG. 10B). A plating resist (22b) having openings (22ba) for forming the second conductor post parts (32b) are formed (FIG. 10C). An electrolytic plating film (28b) is formed in each of the openings (22ba) of the plating resist (22b) (FIG. 11A). The plating resist (22b) is removed. The second conductor post parts (32b) are formed from the electrolytic plating films (28b) (FIG. 11B).

The second insulating layer (30b) is formed on the second conductor post parts (32b) and on the first insulating layer (30a) from a mold resin, and a first intermediate (30a) is completed, which includes the metal foil 24, the first insulating layer (30a), the second insulating layer (30b), the first conductor post parts (32a) and the second conductor post parts (32b). The first insulating layer (30a) and the second insulating layer (30b) have the same component composition. Content of an inorganic filler of the first insulating layer (30a) and the second insulating layer (30b) is 70-85% by weight. A surface of the second insulating layer (30b) and the second conductor post parts (32b) are polished (FIG. 11C). The subsequent manufacturing processes are the same as in the first embodiment.

In the second embodiment, the thickness of each of the first insulating layer (30a) and the second insulating layer (30b) is half that of the insulating layer 30 of the first embodiment. Therefore, the height of each of the first conductor post parts (32a) and the second conductor post parts (32b) that are formed by electrolytic plating is half that of the conductor posts 32 of the first embodiment, and the first conductor post parts (32a) and the second conductor post parts (32b) can be formed in a short time. Further, the conductor posts 32 are each formed to have the two-stage structure that includes the first conductor post part (32a) and the second conductor post part (32b). Therefore, stress acting on the printed wiring board 10 can be relaxed by the conductor post parts (32a, 32b).

In a package substrate, a structure of a cavity substrate with relative to a base structure may be an asymmetric structure. Such a package substrate is likely to warp. Further, due to a stress caused by the warping, a crack is likely to occur in the base substrate directly below the cavity.

A printed wiring board according to an embodiment of the present invention includes: a second circuit substrate that has a mounting area, a third surface, and a fourth surface that is on an opposite side of the third surface; and a first circuit substrate that is laminated on the third surface of the second circuit substrate, has a first surface and a second surface that is on an opposite side of the first surface, and has an opening for exposing the mounting area. The first surface of the first circuit substrate and the third surface of the second circuit substrate oppose each other. The second circuit substrate includes: a first resin insulating layer that has an upper surface and a lower surface that is on an opposite side of the upper surface, and has an opening for a first via conductor, the opening reaching the upper surface from the lower surface; a first conductor layer in the second circuit substrate, the first conductor layer being formed on the lower surface of the first resin insulating layer; and the first via conductor that is formed in the opening for the first via conductor, and is connected to the first conductor layer in the second circuit substrate. The third surface and the upper surface are the same surface. A bottom of the first via conductor that is exposed from the opening forms a pad for mounting an electronic component. The first resin insulating layer contains a reinforcing material. An insulating layer of the first circuit substrate does not contain the reinforcing material.

In a printed wiring board according to an embodiment of the present invention, the bottom of the first via conductor that is exposed from the opening that is formed in the first circuit substrate forms the pad for mounting an electronic component, the first resin insulating layer in the second circuit substrate contains a reinforcing material, and the insulating layer of the first circuit substrate does not contain a reinforcing material. Since the highly rigid first resin insulating layer is used, even for the printed wiring board having the opening for exposing the mounting area, a stress caused by warpage can be suppressed. Further, since the other insulating layer does not contain a reinforcing material, an overall thickness can be reduced.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a first circuit substrate having a first surface and a second surface on an opposite side with respect to the first surface; and
a second circuit substrate having a third surface and a fourth surface on an opposite side with respect to the third surface such that the first circuit substrate is laminated on the third surface and that the first surface and the third surface are opposing each other,
wherein the second circuit substrate comprises a first conductor layer, a first resin insulating layer including a reinforcing material and formed on the first conductor layer, and a plurality of mounting via conductors formed in the first resin insulating layer and connected to the first conductor layer such that the second circuit substrate has a mounting area on the third surface and that the plurality of mounting via conductors has a plurality of via bottoms forming a plurality of pads and positioned to mount an electronic component in the mounting area, respectively, and the first circuit substrate comprises an insulating layer which does not contain a reinforcing material and has an opening portion formed through the insulating layer and exposing the plurality of via bottoms forming the plurality of pads formed in the mounting area.

2. A printed wiring board according to claim 1, wherein the second circuit substrate comprises a plurality of resin insulating layers which do not contain a reinforcing material.

3. A printed wiring board according to claim 1, wherein the first circuit substrate comprises a plurality of conductor posts penetrating through the first circuit substrate such that the plurality of conductor posts is extending from the first surface to the second surface.

4. A printed wiring board according to claim 3, wherein the plurality of conductor posts is formed such that the plurality of conductor posts has a plurality of surfaces substantially on a same plane with the first surface, respectively.

5. A printed wiring board according to claim 4, wherein the first circuit substrate has a plurality of via conductors formed in the first resin insulating layer such that the plurality of via conductors is directly connected to the plurality of conductor posts, respectively.

6. A printed wiring board according to claim 1, wherein the first resin insulating layer of the second circuit substrate has a recess portion formed such that the recess portion is connected to the opening portion of the first circuit substrate and forming a bottom portion of the opening portion.

7. A printed wiring board according to claim 2, wherein the first circuit substrate comprises a plurality of conductor posts penetrating through the first circuit substrate such that the plurality of conductor posts is extending from the first surface to the second surface.

8. A printed wiring board according to claim 7, wherein the plurality of conductor posts is formed such that the plurality of conductor posts has a plurality of surfaces substantially on a same plane with the first surface, respectively.

9. A printed wiring board according to claim 8, wherein the first circuit substrate has a plurality of via conductors formed in the first resin insulating layer such that the plurality of via conductors is directly connected to the plurality of conductor posts, respectively.

10. A printed wiring board according to claim 2, wherein the first resin insulating layer of the second circuit substrate has a recess portion formed such that the recess portion is connected to the opening portion of the first circuit substrate and forming a bottom portion of the opening portion.

11. A printed wiring board according to claim 3, wherein the first resin insulating layer of the second circuit substrate has a recess portion formed such that the recess portion is connected to the opening portion of the first circuit substrate and forming a bottom portion of the opening portion.

12. A printed wiring board according to claim 4, wherein the first resin insulating layer of the second circuit substrate has a recess portion formed such that the recess portion is connected to the opening portion of the first circuit substrate and forming a bottom portion of the opening portion.

13. A printed wiring board according to claim 5, wherein the first resin insulating layer of the second circuit substrate has a recess portion formed such that the recess portion is connected to the opening portion of the first circuit substrate and forming a bottom portion of the opening portion.

14. A printed wiring board according to claim 9, wherein the first resin insulating layer of the second circuit substrate has a recess portion formed such that the recess portion is connected to the opening portion of the first circuit substrate and forming a bottom portion of the opening portion.

15. A method for manufacturing a printed wiring board, comprising:
forming, on a support plate, an insulating layer of a first circuit substrate;
forming a frame-shaped groove for an opening portion of the first circuit substrate in the insulating layer such that the frame-shaped groove reaches the support plate;
forming a release layer on a surface of the insulating layer such that the release layer extends to cover the frame-shaped groove;
forming, on the surface of the insulating layer, a first resin insulating layer of a second circuit substrate such that the first resin insulating layer covers the release layer formed on the insulating layer of the first circuit substrate;
removing the support plate from the insulating layer of a first circuit substrate such that the support plate is separated from a structure comprising the insulating layer of the first circuit substrate and the first resin insulating layer of the second circuit substrate;
removing a portion of the insulating layer surrounded by the frame-shaped groove from the structure comprising the insulating layer of the first circuit substrate and the first resin insulating layer of the second circuit substrate such that the opening portion is formed in the insulating layer of the first circuit substrate; and
removing the release layer from the structure comprising the insulating layer of the first circuit substrate and the first resin insulating layer of the second circuit substrate such that a mounting area for mounting an electronic component on the second circuit substrate is formed by exposing in the opening portion of the insulating layer,
wherein the insulating layer of the first circuit substrate does not contain a reinforcing material, and the first resin insulating layer of the second circuit substrate comprises a reinforcing material.

16. A method for manufacturing a printed wiring board according to claim 15, further comprising:
forming, on the first resin insulating layer of the second circuit substrate, a plurality of resin insulating layers of the second circuit substrate,
wherein the plurality of resin insulating layers do not contain a reinforcing material.

17. A method for manufacturing a printed wiring board according to claim 15, further comprising:
forming a plurality of conductor posts of the first circuit substrate such that the plurality of conductor posts penetrates through the first circuit substrate and extends from a first surface of the first circuit substrate to a second surface of first circuit substrate on an opposite side with respect to the first surface.

18. A method for manufacturing a printed wiring board according to claim 17, further comprising:
forming a plurality of via conductors in the first resin insulating layer of the second circuit substrate such that the plurality of via conductors is directly connected to the plurality of conductor posts, respectively.

19. A method for manufacturing a printed wiring board according to claim 18, further comprising:
forming the plurality of conductor posts such that the plurality of conductor posts has a plurality of surfaces substantially on a same plane with the first surface of the first circuit substrate, respectively.

20. A method for manufacturing a printed wiring board according to claim 15, wherein the removing of the release layer comprises forming, in the first resin insulating layer of the second circuit substrate, a recess portion such that the recess portion is connected to the opening portion of the first circuit substrate and forms a bottom portion of the opening portion.
